(19) United States
(12) Patent Application Publication
(10) Pub. No.: US 2014/0049294 A1
(43) Pub. Date: Feb. 20, 2014

(54) INPUT BUFFER

(71) Applicant: KABUSHIKI KAISHA TOSHIBA, Tokyo (JP)

(72) Inventor: Kosuke YANAGIDAIRA, Kanagawa (JP)

(73) Assignee: Kabushiki Kaisha Toshiba, Tokyo (JP)

(21) Appl. No.: 13/753,721

(22) Filed: Jan. 30, 2013

Related U.S. Application Data
(60) Provisional application No. 61/684,023, filed on Aug. 16, 2012.

(51) Int. Cl. H03K 3/01

(52) U.S. Cl. CPC H03K 3/01
USPC 327/108

(57) ABSTRACT

According to one embodiment, an input buffer includes a comparator that compares an input signal with a reference voltage, an inverter that inverts an output signal of the comparator, and a drive adjusting circuit that adjusts a current driving force of the inverter.

### CROSS-REFERENCE TO RELATED APPLICATIONS

This application is based upon and claims the benefit of priority from Provisional Patent Application No. 61/684,023, filed on Aug. 16, 2012; the entire contents of which are incorporated herein by reference.

### FIELD

Embodiments described herein relate generally to an input buffer.

### BACKGROUND

There are input buffers in which a comparator is connected at a preceding stage of an inverter. In this input buffer, when a reference voltage of the comparator becomes high, the low level of the output of the comparator increases, therefore, skew increases in some cases.

### BRIEF DESCRIPTION OF THE DRAWINGS

FIG. 1 is a circuit diagram illustrating a schematic configuration of an input buffer according to a first embodiment;

FIG. 2A is a waveform chart illustrating the relationship between a reference voltage VREF and an input signal IN when the reference voltage VREF is low in the input buffer in FIG. 1, FIG. 2B is a diagram illustrating a waveform of an output signal OUTn of a comparator 1 with respect to the input signal IN in FIG. 2A, and FIG. 2C is a diagram illustrating a waveform of an output signal OUT of an inverter 2 with respect to the output signal OUTn in FIG. 2B;

FIG. 3A is a waveform chart illustrating the relationship between the reference voltage VREF and the input signal IN when the reference voltage VREF is high in the input buffer in FIG. 1, FIG. 3B is a diagram illustrating a waveform of the output signal OUTn of the comparator 1 with respect to the input signal IN in FIG. 3A, and FIG. 3C is a diagram illustrating a waveform of the output signal OUT of the inverter 2 with respect to the output signal OUTn in FIG. 3B;

FIG. 4A is a diagram illustrating the relationship between the value of a variable resistor R1 in FIG. 1 and the value of the output signal OUTn when the output signal OUT rises, FIG. 4B is a diagram illustrating the relationship between the waveform of the output signal OUTn and the value of the variable resistor R1 when the reference voltage VREF is low, and FIG. 4C is a diagram illustrating the relationship between the waveform of the output signal OUTn and the value of the variable resistor R1 when the reference voltage VREF is high;

FIG. 5 is a circuit diagram illustrating a schematic configuration of an input buffer according to a second embodiment;

FIG. 6 is a circuit diagram illustrating a schematic configuration of an input buffer according to a third embodiment;

FIG. 7 is a circuit diagram illustrating a schematic configuration of an input buffer according to a fourth embodiment;

FIG. 8 is a circuit diagram illustrating a schematic configuration of an input buffer according to a fifth embodiment;

FIG. 9 is a circuit diagram illustrating a schematic configuration of an input buffer according to a sixth embodiment;

FIG. 10 is a circuit diagram illustrating a schematic configuration of an input buffer according to a seventh embodiment;

FIG. 11 is a circuit diagram illustrating a schematic configuration of an input buffer according to an eighth embodiment;

FIG. 12 is a circuit diagram illustrating a schematic configuration of an input buffer according to a ninth embodiment;

FIG. 13 is a circuit diagram illustrating a schematic configuration of an input buffer according to a tenth embodiment;

FIG. 14 is a circuit diagram illustrating a schematic configuration of an input buffer according to an eleventh embodiment;

FIG. 15A is a block diagram illustrating a schematic configuration of a semiconductor memory device to which the input buffer according to a twelfth embodiment is applied, FIG. 15B is a perspective view illustrating a schematic configuration of a NAND memory 33-1 in FIG. 15A, and FIG. 15C is a perspective view illustrating a schematic configuration of a memory chip CP1 of the NAND memory 33-1 in FIG. 15B;

FIG. 16 is a perspective view illustrating an example of a schematic configuration of the NAND memory 33-1 in FIG. 15A; and

FIG. 17 is a timing chart illustrating the relationship between a data strobe signal DQS and a data signal DQ input to an input buffer 41 in FIG. 15C.

### DETAILED DESCRIPTION

According to embodiments, a comparator, an inverter, and a drive adjusting circuit are provided. The comparator compares an input signal with a reference voltage. The inverter inverts an output signal of the comparator. The drive adjusting circuit adjusts a current driving force of the inverter.

An input buffer according to the embodiments will be explained below in detail with reference to the accompanying drawings. The present invention is not limited to these embodiments.

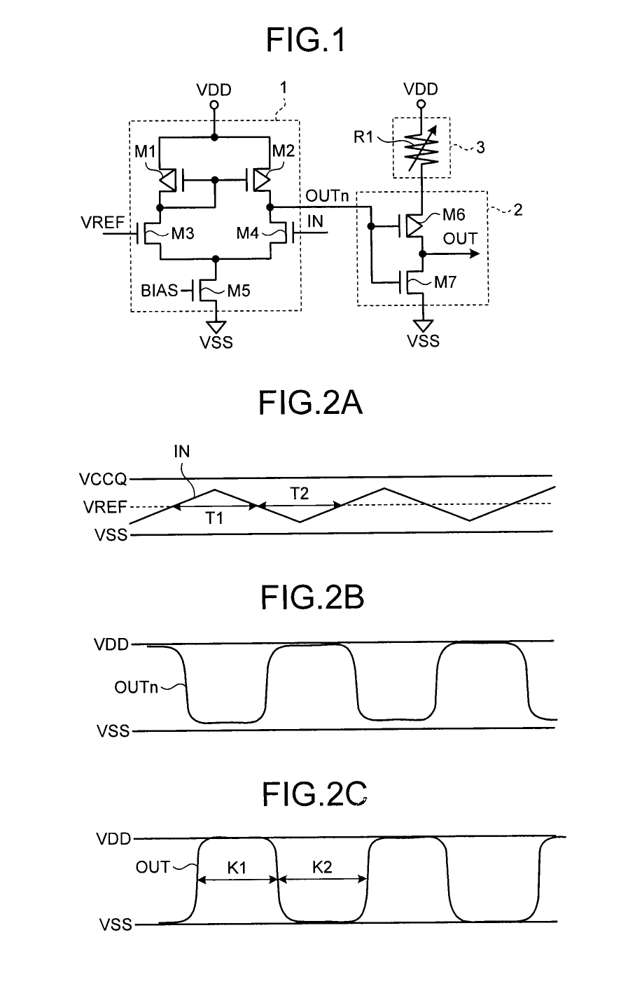

FIG. 1 is a circuit diagram illustrating a schematic configuration of an input buffer according to a first embodiment.

In FIG. 1, in this input buffer, a comparator 1, an inverter 2, and a drive adjusting circuit 3 are provided. The comparator 1 can compare an input signal IN with a reference voltage VREF. The comparator 1 can use a differential amplifier that performs a current mirror operation. The inverter 2 can invert an output signal OUTn of the comparator 1. The drive adjusting circuit 3 can adjust the current driving force of the inverter 2.

In the comparator 1, P-channel field-effect transistors M1 and M2 and N-channel field-effect transistors M3 to M5 are provided. The sources of the P-channel field-effect transistors M1 and M2 are connected to a first power supply potential VDD. The gates of the P-channel field-effect transistors M1 and M2 are connected to the drain of the N-channel field-effect transistor M3. The N-channel field-effect transistor M3 is connected in series with the P-channel field-effect transistor M1 and the N-channel field-effect transistor M4 is connected in series with the P-channel field-effect transistor M2. The sources of the N-channel field-effect transistors M3 and M4 are connected to the drain of the N-channel field-effect transistor M5 and the source of the N-channel field-effect transistor M5 is connected to a second power supply potential VSS. The reference voltage VREF is input to the gate of the N-channel field-effect transistor M3, the input signal IN is input to the gate of the N-channel field-effect transistor M4, and a bias voltage BIAS is input to the gate of the N-channel field-effect transistor M5.

In the inverter 2, a P-channel field-effect transistor M6 and an N-channel field-effect transistor M7 are provided. A variable resistor R1 is provided in the drive adjusting circuit 3. The P-channel field-effect transistor M6 is connected in series with the N-channel field-effect transistor M7. The gate of the P-channel field-effect transistor M6 and the gate of the N-channel field-effect transistor M7 are connected to the drain of the N-channel field-effect transistor M4. The source of the P-channel field-effect transistor M6 is connected to the first power supply potential VDD via the variable resistor R1. The source of the N-channel field-effect transistor M7 is connected to the second power supply potential VSS.

Then, the current flowing in the N-channel field-effect transistor M4 is set by the current mirror operation of the P-channel field-effect transistors M1 and M2 and the input signal IN and the reference voltage VREF are compared in the N-channel field-effect transistors M3 and M4. Then, when the input signal IN exceeds the reference voltage VREF, the current flowing in the N-channel field-effect transistor M4 intends to increase, however, the drain potential of the N-channel field-effect transistor M4 decreases to maintain the current flowing in the N-channel field-effect transistor M4 to a predetermined value, whereby the output signal OUTn is pulled down to a low level. On the other hand, when the input signal IN falls below the reference voltage VREF, the current flowing in the N-channel field-effect transistor M4 intends to decrease, however, the drain potential of the N-channel field-effect transistor M4 increases to maintain the current flowing in the N-channel field-effect transistor M4 to a predetermined value, whereby the output signal OUTn is pulled up to a high level. Then, the output signal OUTn of the comparator 1 is input to the inverter 2 and the output signal OUTn is inverted in the inverter 2, whereby an output signal OUT is output.

When the value of the reference voltage VREF varies, the low level of the output signal OUTn varies and the skew of the output signal OUT varies. Therefore, the current driving force on the pull-up side of the inverter 2 can be adjusted by adjusting the value of the variable resistor R1 in accordance with the value of the reference voltage VREF. Therefore, the rising performance of the output signal OUT can be adjusted in accordance with the variation of the low level of the output signal OUTn. Thus, it is possible to compensate for the variation of the skew of the output signal OUT in accordance with the variation of the value of the reference voltage VREF.

FIG. 2A is a waveform chart illustrating the relationship between the reference voltage VREF and the input signal IN when the reference voltage VREF is low in the input buffer in FIG. 1, FIG. 2B is a diagram illustrating a waveform of the output signal OUTn of the comparator 1 with respect to the input signal IN in FIG. 2A, and FIG. 2C is a diagram illustrating a waveform of the output signal OUT of the inverter 2 with respect to the output signal OUTn in FIG. 2B.

In FIG. 2A, a power supply voltage VCCQ is 1.8 V and the reference voltage VREF is VCCQ/2=0.9 V. Moreover, a period T1 in which the input signal IN exceeds the reference voltage VREF is equal to a period T2 in which the input signal IN falls below the reference voltage VREF.

At this time, as shown in FIG. 2B, in the period T1, the low level of the output signal OUTn is sufficiently pulled down to around the second power supply potential VSS, and in the period T2, the high level of the output signal OUTn is sufficiently pulled up to around the first power supply potential VDD.

Consequently, as shown in FIG. 2C, the output signal OUT rapidly rises in response to the falling of the output signal OUTn and the output signal OUT rapidly falls in response to the rising of the output signal OUTn. Therefore, a high level period K1 of the output signal OUT becomes equal to a low level period K2 of the output signal OUT and thus, the skew of the output signal OUT becomes small.

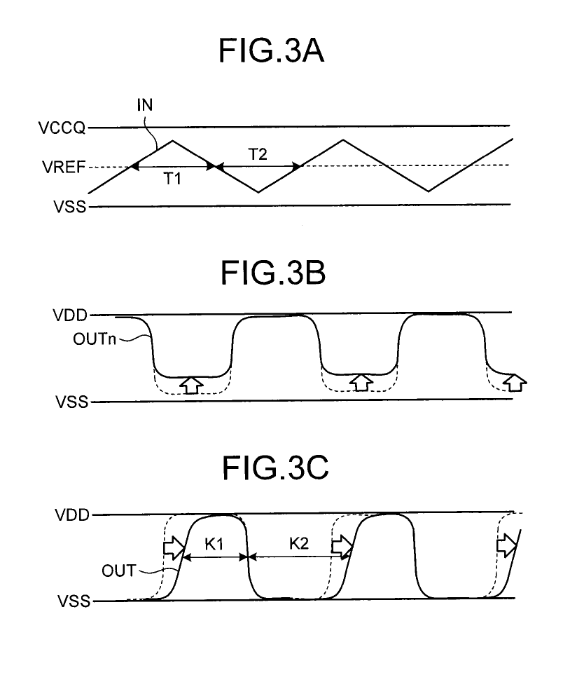

FIG. 3A is a waveform chart illustrating the relationship between the reference voltage VREF and the input signal IN when the reference voltage VREF is high in the input buffer in FIG. 1, FIG. 3B is a diagram illustrating a waveform of the output signal OUTn of the comparator 1 with respect to the input signal IN in FIG. 3A, and FIG. 3C is a diagram illustrating a waveform of the output signal OUT of the inverter 2 with respect to the output signal OUTn in FIG. 3B.

In FIG. 3A, the power supply voltage VCCQ is 3.3 V and the reference voltage VREF is VCCQ/2=1.65 V. Moreover, the period T1 in which the input signal IN exceeds the reference voltage VREF is equal to the period T2 in which the input signal IN falls below the reference voltage VREF.

At this time, as shown in FIG. 3B, in the period T2, the high level of the output signal OUTn is sufficiently pulled up to around the first power supply potential VDD. On the other hand, in the period T1, if the reference voltage VREF is high, the resistance of the N-channel field-effect transistor M3 decreases and the common source potential of the N-channel field-effect transistors M3 and M4 increases, therefore, the low level of the output signal OUTn is not sufficiently pulled down to around the second power supply potential VSS.

Consequently, as shown in FIG. 3C, whereas the output signal OUT rapidly falls in response to the rising of the output signal OUTn, rising of the output signal OUT in response to the falling of the output signal OUTn is delayed. Therefore, the high level period K1 of the output signal OUT becomes shorter than the low level period K2 of the output signal OUT and thus, the skew of the output signal OUT becomes large.

When the reference voltage VREF is high, the current driving force on the pull-up side of the inverter 2 can be increased by decreasing the value of the variable resistor R1. Therefore, rising of the output signal OUT in response to the falling of the output signal OUTn can be made faster. Thus, it is possible to compensate for the delay in rising of the output signal OUT in accordance with the increase of the reference voltage VREF, therefore, the skew of the output signal OUT can be made small.

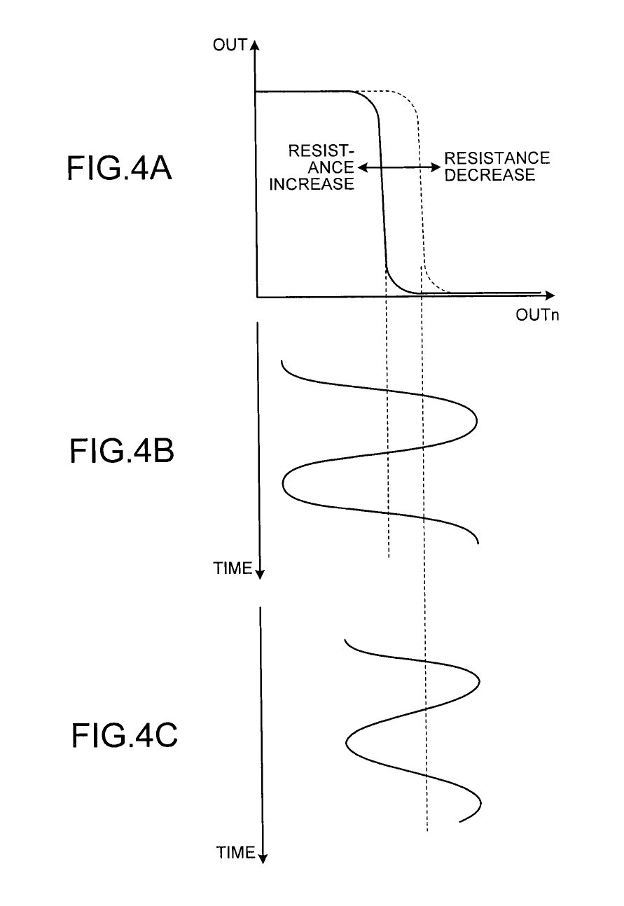

FIG. 4A is a diagram illustrating the relationship between the value of the variable resistor R1 in FIG. 1 and the value of the output signal OUTn when the output signal OUT rises, FIG. 4B is a diagram illustrating the relationship between the waveform of the output signal OUTn and the value of the variable resistor R1 when the reference voltage VREF is low, and FIG. 4C is a diagram illustrating the relationship between the waveform of the output signal OUTn and the value of the variable resistor R1 when the reference voltage VREF is high.

In FIG. 4A, the value of the output signal OUTn when the output signal OUT rises can be adjusted in accordance with the value of the variable resistor R1. Then, as shown in FIG. 4B and FIG. 4C, rising of the output signal OUT can be made to coincide with the intermediate level of the output signal OUTn by adjusting the value of the variable resistor R1 in accordance with the low level of the output signal OUTn. Therefore, the skew of the output signal OUT can be made small.

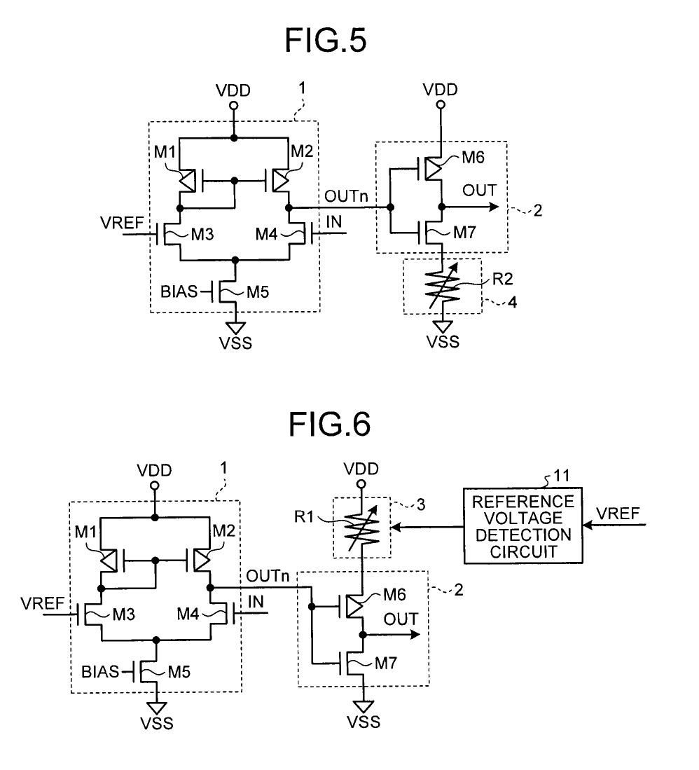

FIG. 5 is a circuit diagram illustrating a schematic configuration of an input buffer according to a second embodiment.

In FIG. 5, in this input buffer, a drive adjusting circuit 4 is provided instead of the drive adjusting circuit 3 of the input buffer in FIG. 1. A variable resistor R2 is provided in the drive adjusting circuit 4. The source of an N-channel field-effect transistor M7 is connected to the second power supply potential VSS via the variable resistor R2.

Then, the current driving force on the pull-down side of the inverter 2 can be adjusted by adjusting the value of the variable resistor R2 in accordance with the value of the reference voltage VREF. Therefore, the falling performance of the output signal OUT can be adjusted in accordance with the variation of the low level of the output signal OUTn. Thus, it is possible to compensate for the variation of the skew of the output signal OUT in accordance with the variation of the value of the reference voltage VREF.

In other words, when the reference voltage VREF is high, the current driving force on the pull-down side of the inverter 2 can be decreased by increasing the value of the variable resistor R2. Therefore, it is possible to suppress the delay in rising of the output signal OUT in response to the falling of the output signal OUT and thus, the skew of the output signal OUT can be made small.

FIG. 6 is a circuit diagram illustrating a schematic configuration of an input buffer according to a third embodiment.

In FIG. 6, in this input buffer, a reference voltage detection circuit 21 is added to the input buffer in FIG. 1. The reference voltage detection circuit 21 can adjust the value of the variable resistor R1 on the basis of the reference voltage VREF input to the comparator 1. For example, when the reference voltage VREF becomes high, the reference voltage detection circuit 11 decreases the value of the variable resistor R1 and therefore can increase the current driving force on the pull-up side of the inverter 2. Consequently, the rising performance of the output signal OUT can be adjusted in accordance with the variation of the reference voltage VREF. Thus, it is possible to compensate for the variation of the skew of the output signal OUT in accordance with the variation of the value of the reference voltage VREF.

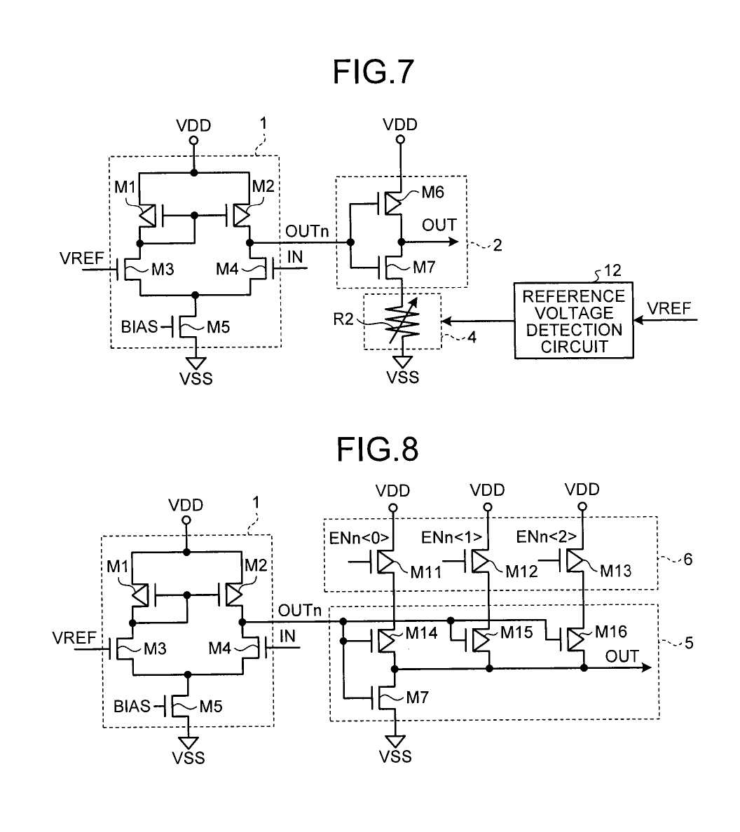

FIG. 7 is a circuit diagram illustrating a schematic configuration of an input buffer according to a fourth embodiment.

In FIG. 7, in this input buffer, a reference voltage detection circuit 22 is added to the input buffer in FIG. 5. The reference voltage detection circuit 22 can adjust the value of the variable resistor R2 on the basis of the reference voltage VREF input to the comparator 1. For example, when the reference voltage VREF becomes high, the reference voltage detection circuit 12 increases the value of the variable resistor R2 and therefore can decrease the current driving force on the pull-down side of the inverter 2. Consequently, the falling performance of the output signal OUT can be adjusted in accordance with the variation of the reference voltage VREF. Thus, it is possible to compensate for the variation of the skew of the output signal OUT in accordance with the variation of the value of the reference voltage VREF.

FIG. 8 is a circuit diagram illustrating a schematic configuration of an input buffer according to a fifth embodiment.

In FIG. 8, in this input buffer, the comparator 1, an inverter 5, and a drive adjusting circuit 6 are provided. The inverter 5 can change the current driving force on the pull-up side by changing the gate width of a P-channel field-effect transistor. The drive adjusting circuit 6 can adjust the current driving force of the inverter 5 by changing the current driving force on the pull-up side of the inverter 5.

In the inverter 5, a plurality of P-channel field-effect transistors M14 to M16 and the N-channel field-effect transistor M7 are provided. In the example in FIG. 8, three P-channel field-effect transistors M14 to M16 are provided, however, any number of P-channel field-effect transistors equal to or more than two may be provided. In the drive adjusting circuit 6, a plurality of P-channel field-effect transistors M11 to M13 is provided.

The P-channel field-effect transistors M14 to M16 are each connected in series with the N-channel field-effect transistor M7. The gates of the P-channel field-effect transistors M14 to M16 and the gate of the N-channel field-effect transistor M7 are connected to the drain of the N-channel field-effect transistor M4. The sources of the P-channel field-effect transistors M14 to M16 are connected to the first power supply potentials VDD via the P-channel field-effect transistors M11 to M13, respectively. The source of the N-channel field-effect transistor M7 is connected to the second power supply potential VSS. Enable signals ENn<0> to ENn<2> are input to the gates of the P-channel field-effect transistors M11 to M13, respectively.

When the enable signals ENn<0> to ENn<2> become a low level, the P-channel field-effect transistors M11 to M13 are turned on. Therefore, the first power supply potential VDD is supplied to the P-channel field-effect transistors M14 to M16 and the P-channel field-effect transistors M14 to M16 are activated. The current driving force on the pull-up side of the inverter 5 can be adjusted by adjusting the number of the P-channel field-effect transistors to be activated among the P-channel field-effect transistors M14 to M16 in accordance with the enable signals ENn<0> to ENn<2>. Therefore, the rising performance of the output signal OUT can be adjusted in accordance with the variation of the low level of the output signal OUTn. Thus, it is possible to compensate for the variation of the skew of the output signal OUT in accordance with the variation of the value of the reference voltage VREF.

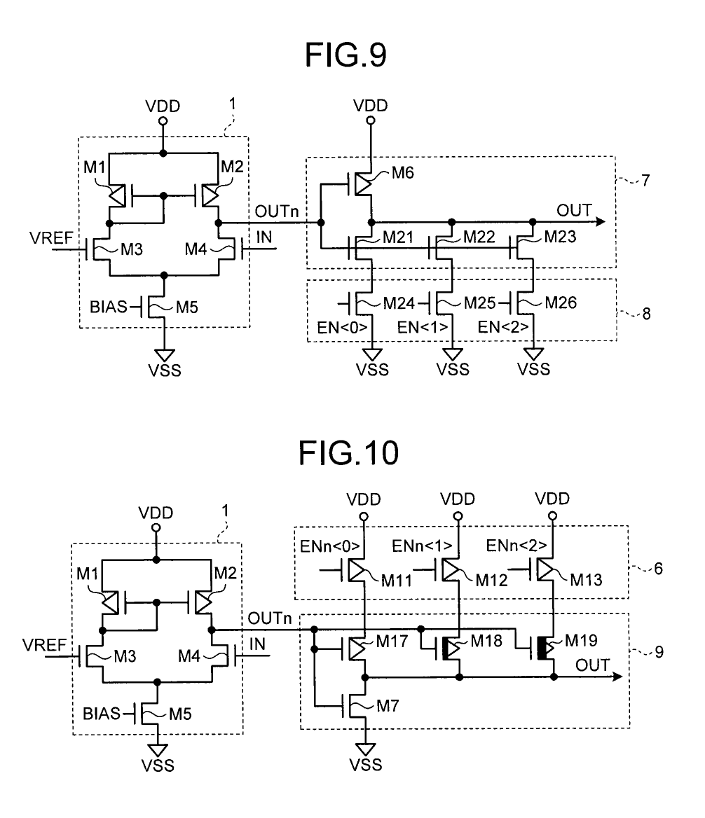

FIG. 9 is a circuit diagram illustrating a schematic configuration of an input buffer according to a sixth embodiment.

In FIG. 9, in this input buffer, the comparator 1, an inverter 7, and a drive adjusting circuit 8 are provided. The inverter 7 can change the current driving force on the pull-down side by changing the gate width of an N-channel field-effect transistor. The drive adjusting circuit 8 can adjust the current driving force of the inverter 7 by changing the current driving force on the pull-down side of the inverter 7.

In the inverter 7, a plurality of N-channel field-effect transistors M21 to M23 and the P-channel field-effect transistor M6 are provided. In the example in FIG. 9, three N-channel field-effect transistors M21 to M23 are provided, however, any number of N-channel field-effect transistors equal to or more than two may be provided. In the drive adjusting circuit 8, a plurality of N-channel field-effect transistors M24 to M26 is provided.

The N-channel field-effect transistors M21 to M23 are each connected in series with the P-channel field-effect transistor M6. The gates of the N-channel field-effect transistors M21 to M23 and the gate of the P-channel field-effect transistor M6 are connected to the drain of the N-channel field-effect transistor M4. The sources of the N-channel field-effect transistors M21 to M23 are connected to the second power supply potentials VSS via the N-channel field-effect transistors M24 to M26, respectively. The source of the P-channel field-effect transistor M6 is connected to the first power supply potential VDD. Enable signals EN<0> to EN<2> are input to the gates of the N-channel field-effect transistors M24 to M26, respectively.

When the enable signals EN<0> to EN<2> become a high level, the N-channel field-effect transistors M24 to M26 are turned on. Therefore, the second power supply potential VSS is supplied to the N-channel field-effect transistors M21 to M23 and the N-channel field-effect transistors M21 to M23 are activated. The current driving force on the pull-down side of the inverter 7 can be adjusted by adjusting the number of the N-channel field-effect transistors to be activated among the N-channel field-effect transistors M21 to M23 in accordance with the enable signals EN<0> to EN<2>. Therefore, the falling performance of the output signal OUT can be adjusted in accordance with the variation of the low level of the output signal OUTn. Thus, it is possible to compensate for the variation of the skew of the output signal OUT in accordance with the variation of the value of the reference voltage VREF.

FIG. 10 is a circuit diagram illustrating a schematic configuration of an input buffer according to a seventh embodiment.

In FIG. 10, in this input buffer, an inverter 9 is provided instead of the inverter 5 in FIG. 8. The inverter 9 can change the current driving force on the pull-up side by changing a threshold voltage of a P-channel field-effect transistor.

In the inverter 9, a plurality of P-channel field-effect transistors M17 to M19 and the N-channel field-effect transistor M7 are provided. In the example in FIG. 10, three P-channel field-effect transistors M17 to M19 are provided, however, any number of P-channel field-effect transistors equal to or more than two may be provided. The threshold voltages of the P-channel field-effect transistors M17 to M19 can be made different from each other.

The P-channel field-effect transistors M17 to M19 are each connected in series with the N-channel field-effect transistor M7. The gates of the P-channel field-effect transistors M17 to M19 and the gate of the N-channel field-effect transistor M7 are connected to the drain of the N-channel field-effect transistor M4. The sources of the P-channel field-effect transistors M17 to M19 are connected to the first power supply potentials VDD via the P-channel field-effect transistors M11 to M13, respectively.

Then, when the enable signals ENn<0> to ENn<2> become a low level, the P-channel field-effect transistors M11 to M13 are turned on. Therefore, the first power supply potential VDD is supplied to the P-channel field-effect transistors M17 to M19 and the P-channel field-effect transistors M17 to M19 are activated. The current driving force on the pull-up side of the inverter 9 can be adjusted by switching the P-channel field-effect transistor to be activated among the P-channel field-effect transistors M17 to M19 in accordance with the enable signals ENn<0> to ENn<2>. Therefore, the rising performance of the output signal OUT can be adjusted in accordance with the variation of the low level of the output signal OUTn. Thus, it is possible to compensate for the variation of the skew of the output signal OUT in accordance with the variation of the value of the reference voltage VREF.

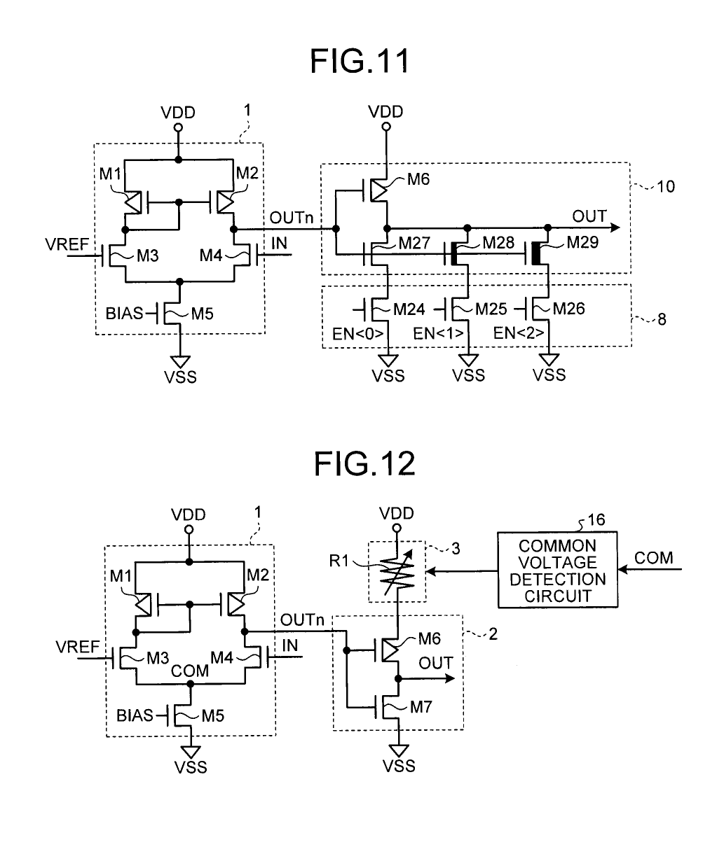

FIG. 11 is a circuit diagram illustrating a schematic configuration of an input buffer according to an eighth embodiment.

In FIG. 11, in this input buffer, an inverter 10 is provided instead of the inverter 7 in FIG. 9. The inverter 10 can change the current driving force on the pull-down side by changing a threshold voltage of an N-channel field-effect transistor.

In the inverter 10, a plurality of N-channel field-effect transistors M27 to M29 and the P-channel field-effect transistor M6 are provided. In the example in FIG. 11, three N-channel field-effect transistors M27 to M29 are provided, however, any number of N-channel field-effect transistors equal to or more than two may be provided. The threshold voltages of the N-channel field-effect transistors M27 to M29 can be made different from each other.

The N-channel field-effect transistors M27 to M29 are each connected in series with the P-channel field-effect transistor M6. The gates of the N-channel field-effect transistors M27 to M29 and the gate of the P-channel field-effect transistor M6 are connected to the drain of the N-channel field-effect transistor M4. The sources of the N-channel field-effect transistors M27 to M29 are connected to the second power supply potentials VSS via the N-channel field-effect transistors M24 to M26, respectively.

Then, when the enable signals EN<0> to EN<2> become a high level, the N-channel field-effect transistors M24 to M26 are turned on. Therefore, the second power supply potential VSS is supplied to the N-channel field-effect transistors M27 to M29 and the N-channel field-effect transistors M27 to M29 are activated. The current driving force on the pull-down side of the inverter 10 can be adjusted by switching the N-channel field-effect transistor to be activated among the N-channel field-effect transistors M27 to M29 in accordance with the enable signals EN<0> to EN<2>. Therefore, the falling performance of the output signal OUT can be adjusted in accordance with the variation of the low level of the output signal OUTn. Thus, it is possible to compensate for the variation of the skew of the output signal OUT in accordance with the variation of the value of the reference voltage VREF.

FIG. 12 is a circuit diagram illustrating a schematic configuration of an input buffer according to a ninth embodiment.

In FIG. 12, in this input buffer, a common voltage detection circuit 16 is added to the input buffer in FIG. 1. The common voltage detection circuit 16 can adjust the value of the variable resistor R1 on the basis of a common source voltage COM of the comparator 1. For example, when the common source voltage COM becomes high, the common voltage detection circuit 16 decreases the value of the variable resistor R1 and therefore can increase the current driving force on the pull-up side of the inverter 2. When the reference voltage VREF becomes high, the resistance of the N-channel field-effect transistor M3 decreases and the common source voltage COM becomes high. Therefore, the rising performance of the output signal OUT can be adjusted in accordance with the variation of the reference voltage VREF. Thus, it is possible to compensate for the variation of the skew of the output signal OUT in accordance with the variation of the value of the reference voltage VREF.

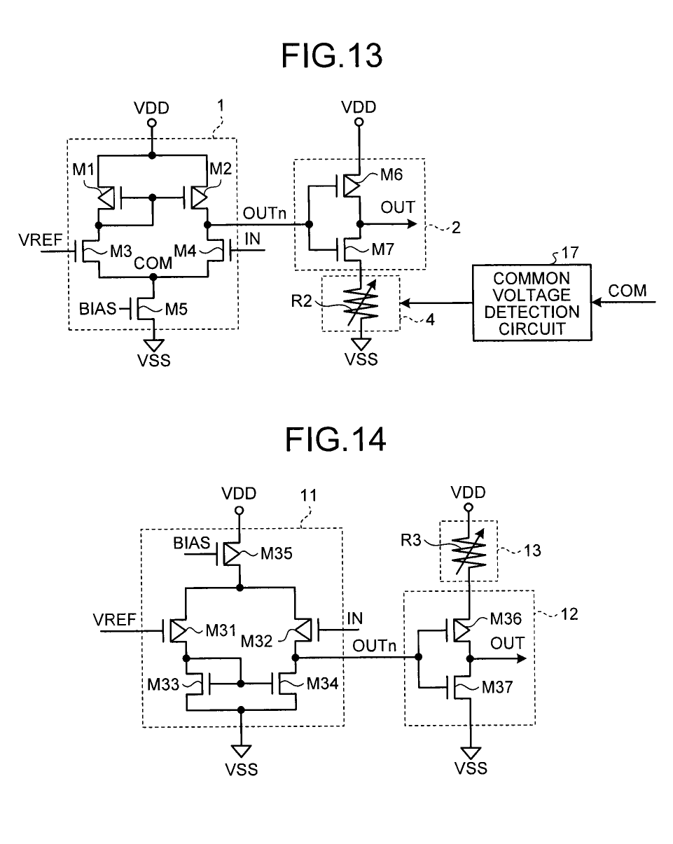

FIG. 13 is a circuit diagram illustrating a schematic configuration of an input buffer according to a tenth embodiment.

In FIG. 13, in this input buffer, a common voltage detection circuit 17 is added to the input buffer in FIG. 5. The common voltage detection circuit 17 can adjust the value of the variable resistor R2 on the basis of the common source voltage COM of the comparator 1. For example, when the common source voltage COM becomes high, the common voltage detection circuit 17 increases the value of the variable resistor R2 and therefore can decrease the current driving force on the pull-up side of the inverter 2. When the reference voltage VREF becomes high, the resistance of the N-channel field-effect transistor M3 decreases and the common source voltage COM becomes high. Therefore, the falling performance of the output signal OUT can be adjusted in accordance with the variation of the reference voltage VREF. Thus, it is possible to compensate for the variation of the skew of the output signal OUT in accordance with the variation of the value of the reference voltage VREF.

FIG. 14 is a circuit diagram illustrating a schematic configuration of an input buffer according to an eleventh embodiment.

In FIG. 14, in this input buffer, a comparator 11, an inverter 12, and a drive adjusting circuit 13 are provided. The comparator 11 can compare the input signal IN with the reference voltage VREF. The inverter 12 can invert the output signal OUTn of the comparator 11. The drive adjusting circuit 13 can adjust the current driving force of the inverter 12.

In the comparator 11, P-channel field-effect transistors M31, M32, and M35 and N-channel field-effect transistors M33 and M34 are provided. The sources of the N-channel field-effect transistors M33 and M34 are connected to the second power supply potential VSS. The gates of the N-channel field-effect transistors M33 and M34 are connected to the drain of the P-channel field-effect transistor M31. The P-channel field-effect transistor M31 is connected in series with the N-channel field-effect transistor M33 and the P-channel field-effect transistor M32 is connected in series with the N-channel field-effect transistor M34. The sources of the P-channel field-effect transistors M31 and M32 are connected to the drain of the P-channel field-effect transistor M35 and the source of the P-channel field-effect transistor M35 is connected to the first power supply potential VDD. The reference voltage VREF is input to the gate of the P-channel field-effect transistor M31, the input signal IN is input to the gate of the P-channel field-effect transistor M32, and the bias voltage BIAS is input to the gate of the P-channel field-effect transistor M35.

In the inverter 12, a P-channel field-effect transistor M36 and an N-channel field-effect transistor M37 are provided. A variable resistor R3 is provided in the drive adjusting circuit 13. The P-channel field-effect transistor M36 is connected in series with the N-channel field-effect transistor M37. The gate of the P-channel field-effect transistor M36 and the gate of the N-channel field-effect transistor M37 are connected to the drain of the P-channel field-effect transistor M32. The source of the P-channel field-effect transistor M36 is connected to the first power supply potential VDD via the variable resistor R3. The source of the N-channel field-effect transistor M37 is connected to the second power supply potential VSS.

Then, the current flowing in the P-channel field-effect transistor M32 is set by the current mirror operation of the N-channel field-effect transistors M33 and M34 and the input signal IN and the reference voltage VREF are compared in the P-channel field-effect transistors M31 and M32. Then, when the input signal IN falls below the reference voltage VREF, the current flowing in the P-channel field-effect transistor M32 intends to increase, however, the drain potential of the P-channel field-effect transistor M32 increases to maintain the current flowing in the P-channel field-effect transistor M32 to a predetermined value, whereby the output signal OUTn is pulled up to a high level. On the other hand, when the input signal IN exceeds the reference voltage VREF, the current flowing in the P-channel field-effect transistor M32 intends to decrease, however, the drain potential of the P-channel field-effect transistor M32 decreases to maintain the current flowing in the P-channel field-effect transistor M32 to a predetermined value, whereby the output signal OUTn is pulled down to a low level. Then, the output signal OUTn of the comparator 11 is input to the inverter 12 and the output signal OUTn is inverted in the inverter 12, whereby the output signal OUT is output.

When the value of the reference voltage VREF varies, the high level of the output signal OUTn varies and the skew of the output signal OUT varies. Therefore, the current driving force on the pull-up side of the inverter 12 can be adjusted by adjusting the value of the variable resistor R3 in accordance with the value of the reference voltage VREF. Therefore, the falling performance of the output signal OUT can be adjusted in accordance with the variation of the high level of the output signal OUTn. Thus, it is possible to compensate for the variation of the skew of the output signal OUT in accordance with the variation of the value of the reference voltage VREF.

In the embodiment in FIG. 14, explanation is given of the method of providing the drive adjusting circuit 13 on the pull-up side of the inverter 12, however, the drive adjusting circuit may be provided on the pull-down side of the inverter 12.

Moreover, the reference voltage detection circuit 11 in FIG. 6 or the common voltage detection circuit 16 in FIG. 12 may be added to the configurations in FIG. 8, FIG. 10, and FIG. 14, and the reference voltage detection circuit 12 in FIG. 7 or the common voltage detection circuit 17 in FIG. 13 may be added to the configurations in FIG. 9 and FIG. 11.

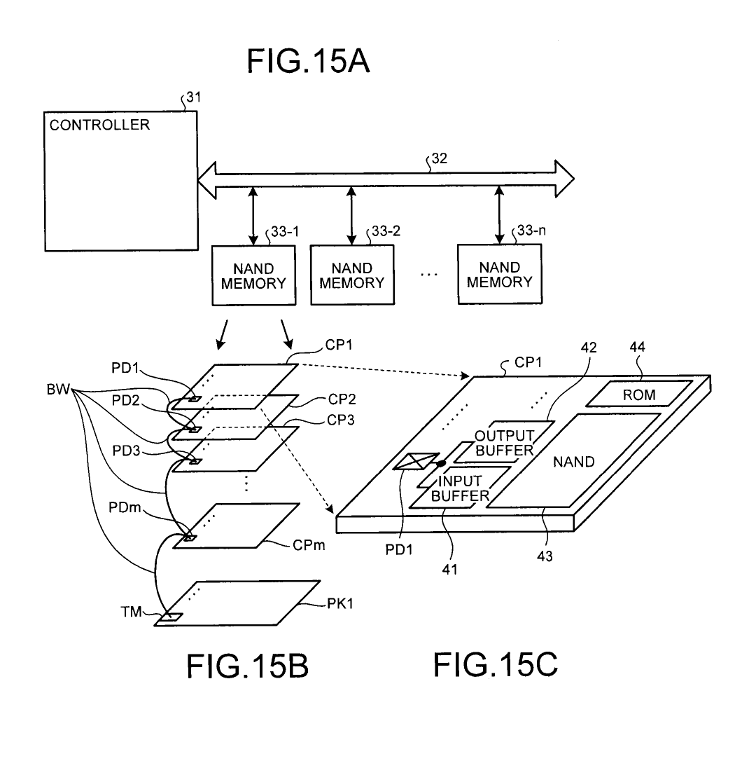

FIG. 15A is a block diagram illustrating a schematic configuration of a semiconductor memory device to which the input buffer according to a twelfth embodiment is applied, FIG. 15B is a perspective view illustrating a schematic configuration of a NAND memory 33-1 in FIG. 15A, and FIG. 15C is a perspective view illustrating a schematic configuration of a memory chip CP1 of the NAND memory 33-1 in FIG. 15B.

In FIG. 15A to FIG. 15C, in the semiconductor memory device, n (n is an integer of two or larger) number of NAND memories 33-1 to 33-n and a controller 31 that performs drive control of the NAND memories 33-1 to 33-n are provided. The drive control of the NAND memories 33-1 to 33-n, for example, includes read/write control, block selection, error correction, wear leveling, and the like of the NAND memories 33-1 to 33-n. Moreover, the controller 31 can transmit a signal among the NAND memories 33-1 to 33-n via a DDR (Double Data Rate) interface.

The NAND memories 33-1 to 33-n are connected to the controller 31 via a channel 32 in parallel with one other. For example, in the NAND memory 33-1, m (m is an integer of two or larger) number of semiconductor chips CP1 to CPm are provided. A NAND flash memory 43 is mounted on each of the semiconductor chips CP1 to CPm, and pad electrodes PD1 to PDm connected to the NAND flash memories 43 are formed on the semiconductor chips CP1 to CPm, respectively. In the NAND flash memory 43, for example, a unit cell array, a decoder, a sense amplifier, a charge pump circuit, a page buffer, and the like can be provided.

In each of the semiconductor chips CP1 to CPm, an input buffer 41, an output buffer 42, and a programmable ROM 44 are provided. The input buffer 41 can transfer write data, a control signal, such as an address, and the like sent from the controller 31, to the NAND flash memory 43 or the like. For the input buffer 41, the configuration shown in any of FIG. 1 and FIG. 5 to FIG. 14 can be used. The output buffer 42 can transfer read data read from the NAND flash memory 43 or the like to the controller 31. The programmable ROM 44 can store various parameters related to the operations of the input buffer 41, the output buffer 42, and the NAND flash memory 43.

Then, m number of the semiconductor chips CP1 to CPm are mounted on one semiconductor package PK1 and an external terminal TM of the semiconductor package PK1 is shared by the pad electrodes PD1 to PDm of the semiconductor chips CP1 to CPm. As a method of mounting the semiconductor chips CP1 to CPm on the semiconductor package PK1, a method of stacking the semiconductor chips CP1 to CPm or a method of arranging the semiconductor chips CP1 to CPm on the same plane may be applied. Moreover, the semiconductor chips CP1 to CPm may be mounted face down or mounted face up on the semiconductor package PK1. Moreover, as a method of causing one external terminal TM to be shared by m number of the pad electrodes PD1 to PDm, m number of the pad electrodes PD1 to PDm and one external terminal TM can be connected with a bonding wire BW. Alternatively, the semiconductor chips CP1 to CPm may be flip-mounted and the pad electrodes PD1 to PDm and the external terminal TM may be connected with each other via bump electrodes formed on the pad electrodes PD1 to PDm. Alternatively, a through electrode may be formed in the semiconductor chips CP1 to CPm and the pad electrodes PD1 to PDm and the external terminal TM may be connected with each other via this through electrode. The same is true for the NAND memories 33-2 to 33-n other than the NAND memory 33-1. Moreover, this semiconductor memory device can be used as a storage device, such as a memory card and an SSD.

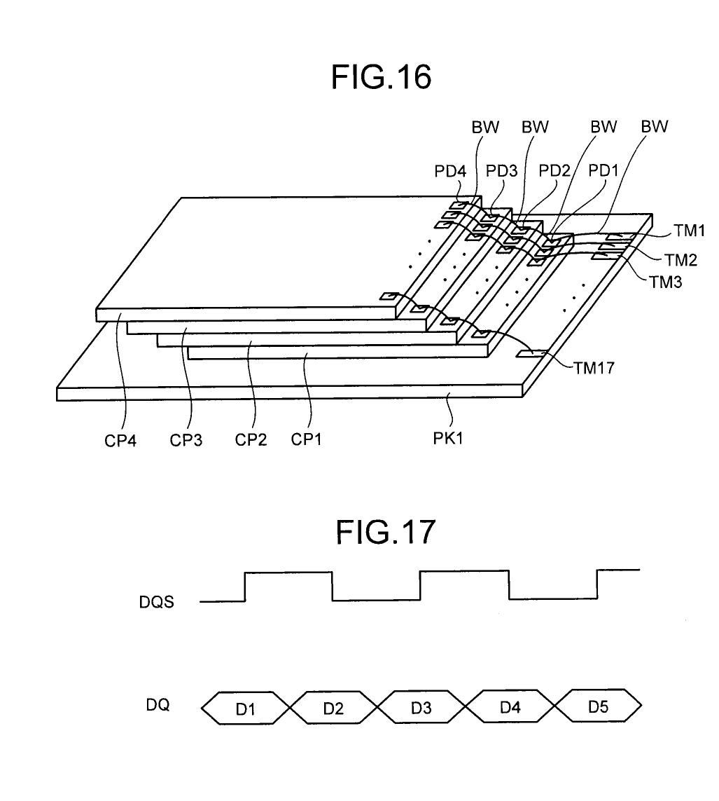

FIG. 16 is a perspective view illustrating an example of a schematic configuration of the NAND memory 33-1 in FIG. 15A. The example in FIG. 16 illustrates a case where m=4 as an example.

In FIG. 16, the pad electrodes PD1 to PD4 are formed on the semiconductor chips CP1 to CP4, respectively. For example, the pad electrodes PD1 to PD4 can be used as an address terminal, a read/write terminal, a chip select terminal, or a data terminal. Moreover, on the semiconductor package PK1, external terminals TM1 to TM17 are formed. Then, when four semiconductor chips CP1 to CP4 are stacked and mounted on the semiconductor package PK1, the semiconductor chips CP1 to CP4 can be stacked in an offset manner so that the pad electrodes PD1 to PD4 are exposed. Then, for example, the pad electrodes PD1 to PD4 are commonly connected to the external terminal TM1 via the bonding wire BW, whereby the pad electrodes PD1 to PD4 of four semiconductor chips CP1 to CP4 can share one external terminal TM1.

FIG. 17 is a timing chart illustrating the relationship between a data strobe signal DQS and a data signal DQ input to the input buffer 41 in FIG. 15C.

In FIG. 17, for example, when the data strobe signal DQS is output from the controller 31, the data strobe signal DQS is input to the input buffer 41 via the pad electrode PD1. Then, the data signal DQ is loaded into the NAND flash memory 43 in response to the rising edge and the falling edge of the data strobe signal DQS.

For the input buffer 41, the skew of the data strobe signal DQS can be reduced by using any of the configurations in FIG. 1 and FIG. 5 to FIG. 14. Therefore, even when transmission of a signal is performed via the DDR interface, the data signal DQ can be loaded stably.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An input buffer comprising:
a comparator that compares an input signal with a reference voltage;
an inverter that inverts an output signal of the comparator; and
a drive adjusting circuit that adjusts a current driving force of the inverter.

2. The input buffer according to claim 1, wherein the drive adjusting circuit includes a first variable resistor that is connected in series with a P-channel field-effect transistor of the inverter.

3. The input buffer according to claim 2, further comprising a reference voltage detection circuit that adjusts a value of the first variable resistor on a basis of the reference voltage.

4. The input buffer according to claim 2, further comprising a common voltage detection circuit that adjusts a value of the first variable resistor on a basis of a common source voltage of the comparator.

5. The input buffer according to claim 1, wherein the drive adjusting circuit includes a second variable resistor that is connected in series with an N-channel field-effect transistor of the inverter.

6. The input buffer according to claim 5, further comprising a reference voltage detection circuit that adjusts a value of the second variable resistor on a basis of the reference voltage.

7. The input buffer according to claim 5, further comprising a common voltage detection circuit that adjusts a value of the second variable resistor on a basis of a common source voltage of the comparator.

8. The input buffer according to claim 1, wherein
the inverter includes
an N-channel field-effect transistor, and
a plurality of P-channel field-effect transistors connected in series with the N-channel field-effect transistor, and
the drive adjusting circuit includes a plurality of select transistors connected in series with the P-channel field-effect transistors, respectively.

9. The input buffer according to claim 8, wherein threshold voltages of the P-channel field-effect transistors are different from each other.

10. The input buffer according to claim 8, wherein the drive adjusting circuit turns the select transistors on on a basis of the reference voltage.

11. The input buffer according to claim 8, wherein the drive adjusting circuit turns the select transistors on on a basis of a common source voltage of the comparator.

12. The input buffer according to claim 1, wherein
the inverter includes
a P-channel field-effect transistor, and
a plurality of N-channel field-effect transistors connected in series with the P-channel field-effect transistor, and
the drive adjusting circuit includes a plurality of select transistors connected in series with the N-channel field-effect transistors, respectively.

13. The input buffer according to claim 12, wherein threshold voltages of the N-channel field-effect transistors are different from each other.

14. The input buffer according to claim 1, wherein the comparator is a differential amplifier that performs a current mirror operation.

15. The input buffer according to claim 1, wherein
the comparator includes
first and second P-channel field-effect transistors that perform a current mirror operation,
a first N-channel field-effect transistor, which is connected in series with the first P-channel field-effect transistor and to a gate of which the reference voltage is input,
a second N-channel field-effect transistor, which is connected in series with the second P-channel field-effect transistor and to a gate of which the input signal is input, and
a third N-channel field-effect transistor, whose drain is connected to a source of the first and second N-channel field-effect transistors and to a gate of which a bias voltage is input.

16. The input buffer according to claim 1, wherein
the comparator includes
first and second N-channel field-effect transistors that perform a current mirror operation,
a first P-channel field-effect transistor, which is connected in series with the first N-channel field-effect transistor and to a gate of which the reference voltage is input,
a second P-channel field-effect transistor, which is connected in series with the second N-channel field-effect transistor and to a gate of which the input signal is input, and
a third P-channel field-effect transistor, whose drain is connected to a source of the first and second P-channel field-effect transistors and to a gate of which a bias voltage is input.

17. The input buffer according to claim 1, wherein an input terminal of the comparator is connected to a pad electrode of a semiconductor chip on which a NAND flash memory is mounted.

18. The input buffer according to claim 17, wherein
a plurality of the semiconductor chips is stacked, and
the pad electrodes are connected to each other between the semiconductor chips via a bonding wire.

19. The input buffer according to claim 18, wherein the pad electrode is connected to a controller that controls driving of the NAND flash memory.

20. The input buffer according to claim 19, wherein the controller performs transmission of a signal between the controller and the semiconductor chip via a DDR interface.
